(19) United States
(12) Patent Application Publication
(10) Pub. No.: US 2025/0275095 A1
(43) Pub. Date: Aug. 28, 2025

(54) LIQUID COOLING SYSTEM AND ELECTRONIC DEVICE

(71) Applicants: INVENTEC (PUDONG) TECHNOLOGY CORPORATION, Shanghai (CN); INVENTEC CORPORATION, Taipei City (TW)

(72) Inventors: Qidong LI, Shanghai (CN); Jingnan ZHAO, Shanghai (CN)

(73) Assignees: INVENTEC (PUDONG) TECHNOLOGY CORPORATION, Shanghai (CN); INVENTEC CORPORATION, Taipei City (TW)

(21) Appl. No.: 18/602,893

(22) Filed: Mar. 12, 2024

(30) Foreign Application Priority Data
Feb. 26, 2024 (CN) 202410211724.4

(51) Int. Cl. H05K 7/20

(52) U.S. Cl. CPC H05K 7/20336; H05K 7/2039

(57) ABSTRACT

An electronic device is configured to accommodate a first cooling fluid and a second cooling fluid, and includes a heat source and a liquid cooling system. The liquid cooling system includes a cooling chamber and a three-dimensional heat transmission apparatus. The cooling chamber is configured to accommodate the first cooling fluid. The three-dimensional heat transmission apparatus is disposed in the cooling chamber, and is configured to accommodate the second cooling fluid. The three-dimensional heat transmission apparatus includes a vapor chamber and at least one heat pipe. The vapor chamber is configured to be thermally coupled to the heat source via the cooling chamber. The at least one heat pipe is disposed on the vapor chamber.

### CROSS-REFERENCE TO RELATED APPLICATIONS

This non-provisional application claims priority under 35 U.S.C. § 119(a) on Patent Application No(s). 202410211724.4 filed in China, on Feb. 26, 2024, the entire contents of which are hereby incorporated by reference.

### BACKGROUND OF THE INVENTION

### Technical Field of the Invention

The invention relates to an electronic device, more particularly to an electronic device having a liquid cooling system.

### Description of the Related Art

A vapor chamber is a type of a liquid cooling device, similar to a heat pipe in the cooling principle, but it differs in the method of heat conduction. Heat pipes transfer heat in one dimension, while vapor chambers transfer heat in two dimensions, making the cooling performance more efficient. Specifically, the vapor chamber mainly includes a chamber and a capillary structure. The chamber has an interior space for accommodating working fluid. The capillary structure is disposed in the interior space. The chamber has an evaporation area for heat absorption and a condensation area for cooling. The working fluid absorbs heat and vaporizes in the evaporation area to rapidly spread to the entire interior space. The vaporized working fluid dissipates heat and condenses back into a liquid form in the condensation area and then returns to the evaporation area via the capillary structure so as to form a cooling cycle.

Generally, in most conventional cooling devices, heat pipes and vapor chambers operate independently, resulting in heat transfer in one dimension or in two dimensions rather than in three-dimensions, such that the heat transfer efficiency of the cooling device is hard to be further improved. Recently, some manufacturers have integrated vapor chambers and heat pipes to create heat transfer devices capable of three-dimensional heat transfer. However, the heat transfer efficiency of the three-dimensional heat transfer devices is still insufficient to meet requirements of users. Therefore, how to further improve the cooling efficiency of the cooling device is an important issue to be solved.

### SUMMARY OF THE INVENTION

The invention provides a liquid cooling system and an electronic device so as to further improve the cooling efficiency of the liquid cooling system.

One embodiment of the invention provides a liquid cooling system configured to accommodate a first cooling fluid and a second cooling fluid and be thermally coupled to a heat source. The liquid cooling system includes a cooling chamber and a three-dimensional heat transmission apparatus. The cooling chamber is configured to accommodate the first cooling fluid. The three-dimensional heat transmission apparatus is disposed in the cooling chamber, and is configured to accommodate the second cooling fluid. The three-dimensional heat transmission apparatus includes a vapor chamber and at least one heat pipe. The vapor chamber is configured to be thermally coupled to the heat source via the cooling chamber. The at least one heat pipe is disposed on the vapor chamber.

Another embodiment of the invention provides an electronic device configured to accommodate a first cooling fluid and a second cooling fluid. The electronic device includes a heat source and a liquid cooling system. The liquid cooling system includes a cooling chamber and a three-dimensional heat transmission apparatus. The cooling chamber is configured to accommodate the first cooling fluid. The three-dimensional heat transmission apparatus is disposed in the cooling chamber, and is configured to accommodate the second cooling fluid. The three-dimensional heat transmission apparatus includes a vapor chamber and at least one heat pipe. The vapor chamber is configured to be thermally coupled to the heat source via the cooling chamber. The at least one heat pipe is disposed on the vapor chamber.

According to the liquid cooling system and the electronic device disclosed by the above embodiment, the three-dimensional heat transmission apparatus is disposed in the cooling chamber, and the cooling chamber and the three-dimensional heat transmission apparatus together form the liquid cooling system. Therefore, the heat source can be cooled via a cooling cycle of the second cooling fluid in the three-dimensional heat transmission apparatus, and the heat absorbed by the second cooling fluid from the heat source can also be further removed via a flow of the first cooling fluid in the cooling chamber. Accordingly, the cooling efficiency of the liquid cooling system can be improved.

### BRIEF DESCRIPTION OF THE DRAWINGS

The invention will become more fully understood from the detailed description given herein below and the accompanying drawings which are given by way of illustration only and thus are not limitative of the invention and wherein:

FIG. 1 is a perspective view of an electronic device omitting a heat source in accordance with one embodiment of the invention;

FIG. 2 is a cross-sectional view of the electronic device in FIG. 1;

FIG. 3 is a top view of a three-dimensional heat transmission apparatus of the electronic device in FIG. 1;

FIG. 4 is a cross-sectional view showing that a first cooling fluid and a second cooling fluid flow in a liquid cooling system of the electronic device in FIG. 1; and

FIG. 5 is a partially cross-sectional view showing that the first cooling fluid and the second cooling fluid flow in the liquid cooling system of the electronic device in FIG. 1.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

In addition, the terms used in the invention, such as technical and scientific terms, have its own meanings and can be comprehended by those skilled in the art, unless the terms are additionally defined in the invention. That is, the terms used in the following paragraphs should be read on the meaning commonly used in the related fields and will not be overly explained, unless the terms have a specific meaning in the invention.

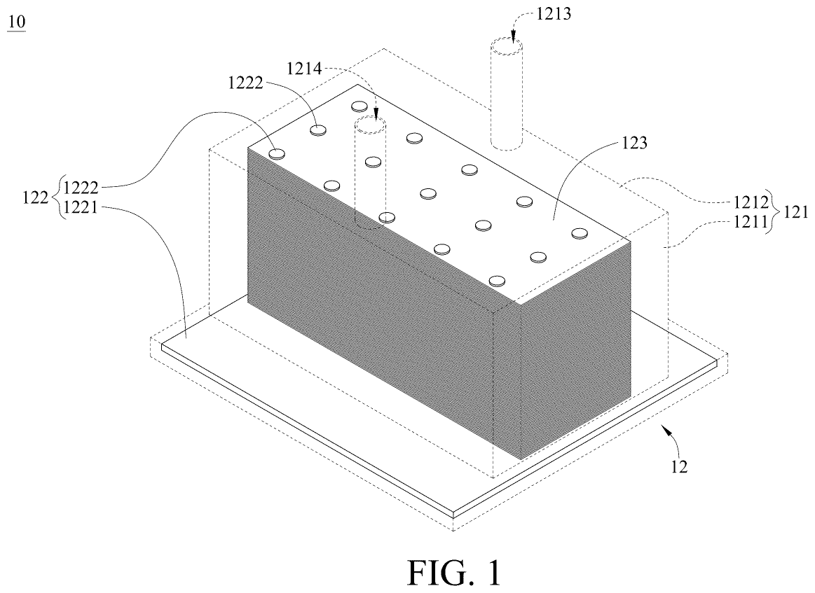

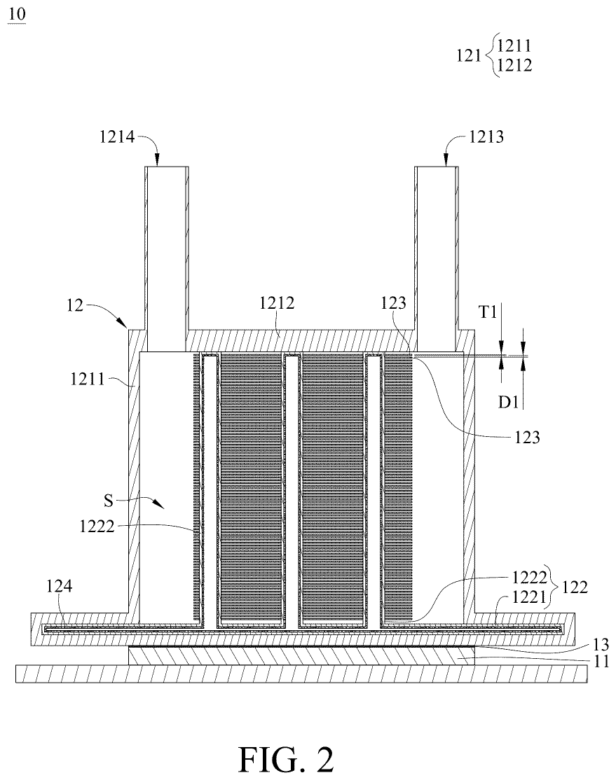

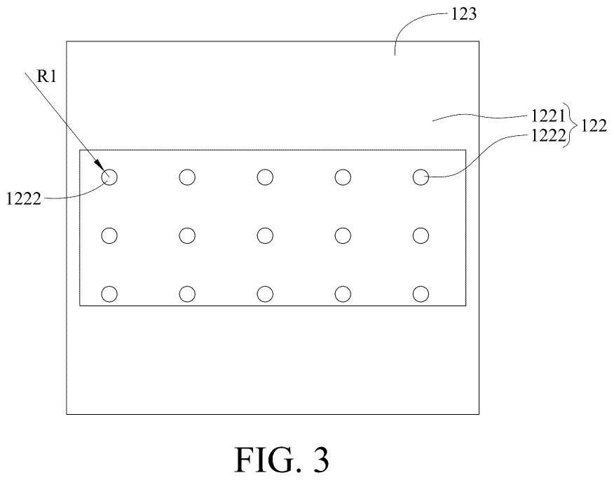

Please refer to FIG. 1 to FIG. 3, where FIG. 1 is a perspective view of an electronic device 10 omitting a heat source 11 in accordance with one embodiment of the invention, FIG. 2 is a cross-sectional view of the electronic device 10 in FIG. 1, and FIG. 3 is a top view of a three-dimensional heat transmission apparatus 122 of the electronic device 10 in FIG. 1.

In this embodiment, the electronic device 10 is configured to accommodate a first cooling fluid (not shown) and a second cooling fluid (not shown). The first cooling fluid and the second cooling fluid are cooling fluid such as water. The electronic device 10 includes a heat source 11, a liquid cooling system 12 and a thermal interface material (TIM) 13. The heat source 11 is, for example, a central processing unit (CPU), but the present invention is not limited thereto.

The liquid cooling system 12 includes a cooling chamber 121 and a three-dimensional heat transmission apparatus 122. The cooling chamber 121 is configured to accommodate the first cooling fluid, and includes a chamber body 1211 and a top plate 1212. The top plate 1212 is disposed on a side of the chamber body 1211. The chamber body 1211 and the top plate 1212 together surround and form an accommodating space S. The cooling chamber 121 has a liquid inlet 1213 and a liquid outlet 1214. The liquid inlet 1213 and the liquid outlet 1214 are located on the top plate 1212, and are in fluid communication with the accommodating space S. That is, the first cooling fluid flows into and out of the accommodating space S via the liquid inlet 1213 and the liquid outlet 1214 located on the top plate 1212. The three-dimensional heat transmission apparatus 122 is located in the accommodating space S, on a side farthest away from the top plate 1212, and the three-dimensional heat transmission apparatus 122 is configured to accommodate the second cooling fluid. The first cooling fluid and the second cooling fluid are, for example, not in fluid contact with each other.

The three-dimensional heat transmission apparatus 122 includes a vapor chamber 1221 and a plurality of heat pipes 1222. The vapor chamber 1221 is thermally coupled to the heat source 11 via the cooling chamber 121. The so-called “thermally coupled to” means thermal contact or connection via other thermally conducting media. In addition, the thermal interface material 13 is coated between the cooling chamber 121 and the heat source 11 so as to further transfer a heat generated by the heat source 11 to the vapor chamber 1221. The heat pipes 1222 are disposed on the vapor chamber 1221, and are arranged in an array. For example, the heat pipes 1222 can be arranged in, for example, a 3×4 array, a 3×5 array or a 2×6 array, but the present invention is not limited thereto. Accordingly, the cooling efficiency can be improved via the heat pipes 1222 arranged in the array. The heat pipes 1222 are, for example, round pipes, and a radius R1 of each heat pipe 1222 is, for example, 2 millimeters.

In this embodiment, the liquid cooling system 12 may include a plurality of fins 123. The fins 123 are disposed on the heat pipes 1222 of the three-dimensional heat transmission apparatus 122, such that the cooling efficiency of the liquid cooling system 12 can be further improved. A thickness T1 of each fin 123 is, for example, 0.2 millimeters, and a distance D1 between adjacent fins 123 is, for example, 0.3 millimeters, but the present invention is not limited thereto.

In this embodiment, the three-dimensional heat transmission apparatus 122 may further include a wick structure 124. Accordingly, after the second cooling fluid absorbs the heat generated by the heat source 11 and vaporizes, the second cooling fluid condenses in the heat pipes 1222 and flows back to the vapor chamber 1221 via the wick structure 124.

In this embodiment, the three-dimensional heat transmission apparatus 122 is disposed in the cooling chamber 121, and the cooling chamber 121 and the three-dimensional heat transmission apparatus 122 together form the liquid cooling system 12. Therefore, the heat source 11 can be cooled via a cooling cycle of the second cooling fluid in the three-dimensional heat transmission apparatus 122, and the heat absorbed by the second cooling fluid from the heat source 11 can also be further removed via a flow of the first cooling fluid in the cooling chamber 121. Accordingly, the cooling efficiency of the liquid cooling system 12 can be improved.

In this embodiment, the three-dimensional heat transmission apparatus 122 includes the plurality of heat pipes 1222, but the present invention is not limited thereto. In other embodiments, the three-dimensional heat transmission apparatus may include one heat pipe merely.

In this embodiment, the heat pipes 1222 are round pipes, but the present invention is not limited thereto. In other embodiments, the heat pipes may be flat pipes or other forms of heat pipes.

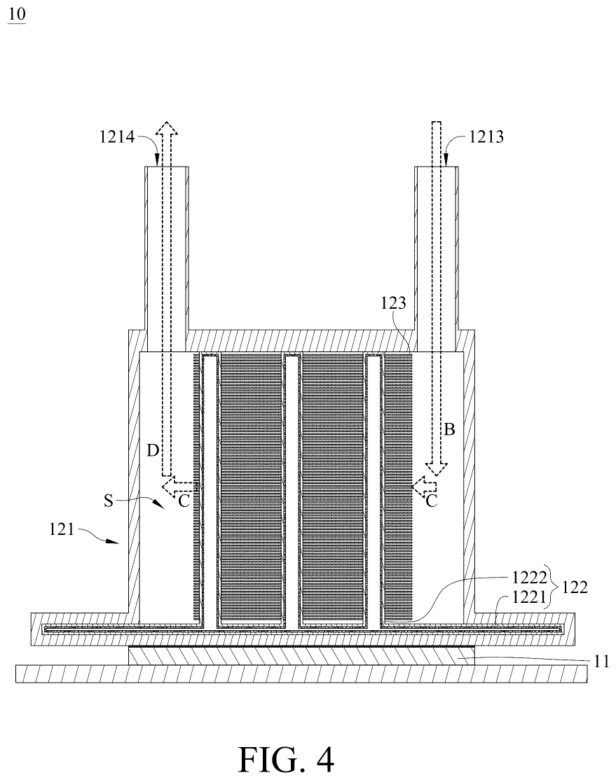

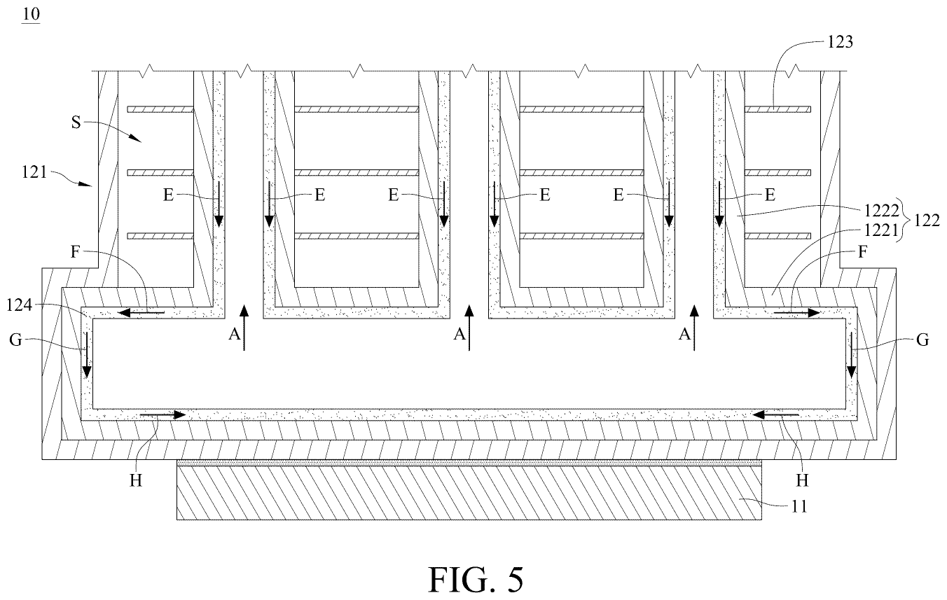

Please refer to FIG. 1 to FIG. 5, where FIG. 4 is a cross-sectional view showing that the first cooling fluid and the second cooling fluid flow in the liquid cooling system 12 of the electronic device 10 in FIG. 1, and FIG. 5 is a partially cross-sectional view showing that the first cooling fluid and the second cooling fluid flow in the liquid cooling system 12 of the electronic device 10 in FIG. 1.

In this embodiment, when the heat generated by the heat source 11 is transferred to the vapor chamber 1221 via the cooling chamber 121, the liquid second cooling fluid located in the vapor chamber 1221 absorbs the heat and vaporizes, and flows to the heat pipes 1222 along a direction A. Meanwhile, the first cooling fluid flows from the liquid inlet 1213 into the accommodating space S along a direction B, and flows through the heat pipes 1222 along a direction C to cool the gaseous second cooling fluid. Then, the first cooling fluid flows out of the accommodating space S via the liquid outlet 1214 along a direction D.

At this time, the gaseous second cooling fluid cooled by the first cooling fluid condenses, and flows back to the vapor chamber 1221 via the wick structure 124 along directions E to H. Accordingly, the heat source 11 can be cooled via the cooling cycle of the second cooling fluid in the three-dimensional heat transmission apparatus 122 and the flow of the first cooling fluid in the cooling chamber 121.

According to the liquid cooling system and the electronic device disclosed by the above embodiment, the three-dimensional heat transmission apparatus is disposed in the cooling chamber, and the cooling chamber and the three-dimensional heat transmission apparatus together form the liquid cooling system. Therefore, the heat source can be cooled via a cooling cycle of the second cooling fluid in the three-dimensional heat transmission apparatus, and the heat absorbed by the second cooling fluid from the heat source can also be further removed via a flow of the first cooling fluid in the cooling chamber. Accordingly, the cooling efficiency of the liquid cooling system can be improved.

It will be apparent to those skilled in the art that various modifications and variations can be made to the invention. It is intended that the specification and examples be considered as exemplary embodiments only, with the scope of the invention being indicated by the following claims.

What is claimed is:

1. A liquid cooling system, configured to accommodate a first cooling fluid and a second cooling fluid and be thermally coupled to a heat source and comprising:
a cooling chamber, configured to accommodate the first cooling fluid; and
a three-dimensional heat transmission apparatus, disposed in the cooling chamber and configured to accommodate the second cooling fluid, wherein the three-dimensional heat transmission apparatus comprises a vapor chamber and at least one heat pipe, the vapor chamber is configured to be thermally coupled to the heat source via the cooling chamber, and the at least one heat pipe is disposed on the vapor chamber.

2. The liquid cooling system according to claim 1, wherein the cooling chamber has an accommodating space, a liquid inlet and a liquid outlet, the three-dimensional heat transmission apparatus is located in the accommodating space, and the liquid inlet and the liquid outlet are in fluid communication with the accommodating space.

3. The liquid cooling system according to claim 2, wherein the cooling chamber comprises a chamber body and a top plate, the top plate is disposed on a side of the chamber body farthest away from the three-dimensional heat transmission apparatus, the chamber body and the top plate together surround and form the accommodating space, and the liquid inlet and the liquid outlet are located on the top plate.

4. The liquid cooling system according to claim 1, further comprising a plurality of fins, wherein the plurality of fins are disposed on the at least one heat pipe of the three-dimensional heat transmission apparatus.

5. The liquid cooling system according to claim 4, wherein a thickness of each of the plurality of fins is 0.2 millimeters.

6. The liquid cooling system according to claim 4, wherein a distance between two of the plurality of fins that are adjacent to each other is 0.3 millimeters.

7. The liquid cooling system according to claim 1, wherein the at least one heat pipe is a round pipe.

8. The liquid cooling system according to claim 1, wherein a radius of the at least one heat pipe is 2 millimeters.

9. The liquid cooling system according to claim 1, wherein the three-dimensional heat transmission apparatus comprises a plurality of heat pipes, and the plurality of heat pipes are arranged in an array.

10. An electronic device, configured to accommodate a first cooling fluid and a second cooling fluid and comprising:
a heat source; and
a liquid cooling system, comprising:
a cooling chamber, configured to accommodate the first cooling fluid; and
a three-dimensional heat transmission apparatus, disposed in the cooling chamber and configured to accommodate the second cooling fluid, wherein the three-dimensional heat transmission apparatus comprises a vapor chamber and at least one heat pipe, the vapor chamber is configured to be thermally coupled to the heat source via the cooling chamber, and the at least one heat pipe is disposed on the vapor chamber.
